(19) United States
(12) Patent Application Publication
(10) Pub. No.: US 2008/0179731 A1
(43) Pub. Date: Jul. 31, 2008

(54) Anti-Impact memory module

(75) Inventor: Wen-Jeng Fan, Hsinchu (TW)

Correspondence Address: TROXELL LAW OFFICE PLLC, SUITE 1404, 5205 LEESBURG PIKE, FALLS CHURCH, VA, 22041, US

(73) Assignee: POWERTECH TECHNOLOGY INC.

(21) Appl. No.: 11/657,715

(22) Filed: Jan. 25, 2007

(51) Int. Cl. H01L 23/13

(52) U.S. Cl. 257/690; 257/E23.004; 257/E23.021; 257/E23.194

(57) ABSTRACT

An anti-impact memory module mainly comprises a multi-layer PWB (Printed Wiring Board), a plurality of memory packages and a plurality of first anti-impact bars. The PWB has two longer sides and two shorter sides. A plurality of gold fingers are disposed along one of the longer sides. The first anti-impact bars are disposed on one surface of the PWB and adjacent to the two shorter sides, which are higher than the memory packages in height. Preferably, at least a second anti-impact bar is formed at another longer side far away from the gold fingers. The first anti-impact bars and/or the second anti-impact bar can be utilized to cushion impact force for preventing the memory module product from damaging while fallen accidentally.

### FIELD OF THE INVENTION

The present invention relates to a memory module including random access memory integrated circuits, more particularly to an anti-impact memory module.

### BACKGROUND OF THE INVENTION

Within numerous electronic products such as personal computer and notebook micro computer, memory module is a critical part, which can be removably plugged into the memory socket of mother board to provide operations of computer system. The high frequency memory module of the present time may include SIMM (Single In-Line Memory Module), DIMM (Dual In-Line Memory Module) and SO-DIMM (Small Outline Dual In-Line Memory Module). Sometimes, the memory module could be dropped accidentally during carrying, conveying and replacing process, but the memory modules of the present time are highly vulnerable to damage because of bad impact resistance.

With reference to FIG. 1, a known memory module 100 comprises a multi-layer PWB 110 (Printed Wiring Board) and a plurality of memory packages 120. The PWB 110 is rigid and has two longer sides 111 and two shorter sides 112. The memory packages 120 are mounted on the PWB 110. A plurality of gold fingers 113 are disposed along one longer side 111 of the PWB 110 and at least an arc notch 114 is formed at each of the two shorter sides respectively for alignment while plugging into a memory socket. A drop test is performed to confirm impact resistance of the known memory module 100. Referring to FIG. 2, the known memory module 100 is placed at a predetermined height H, such as from 50 cm to 100 cm and falls like a free falling body from diverse angles to impact cement ground 10. Then, the fallen memory module 100 will be checked if it normally functions. Unfortunately, the memory modules 100 of the present time have been confirmed that they are highly subject to damage for impact hard to pass impact test and it has been found that the joint interface between the PWB 100 and the memory packages 120 is always broken resulting in electrical disconnection.

Referring to FIG. 3, the memory packages 120 may generally be BGA (Ball Grid Array) packages and has a plurality of solder balls 121 mounted onto the ball pads 122 of the substrate and are not covered by a solder resist layer 123. Besides, a plurality of ball-mounting pads 115 are disposed on the PWB 110 and exposed on the solder resist layer 116 for mounting the solder balls 121. While the memory module 100 is fallen as a free falling body to impact PWB 110, a stress from the PWB 110 is conducted to the memory packages 120 to cause cracks 124 at mounting interfaces between the solder balls 121 and the ball pads 122 or between the solder balls 121 and the ball-mounting pads 115, which enables the entire memory module 100 product not to normally work.

### SUMMARY OF THE INVENTION

The primary object of the present invention is to provide an anti-impact memory module, which enables to cushion impact force by utilizing anti-impact bars on the PWB to prevent the memory module from electrical disconnection resulting in product failure when it falls and further not to be subject to collision of external force and to avoid the memory chip from being destroyed due to electrostatic discharge.

The secondary object of the present invention is to provide an anti-impact memory module, which controls the mass density of anti-impact bars to prevent from excessively increasing total weight of the memory module to affect drop test result.

One aspect of the present invention provides a memory module that mainly comprises a multi-layer PWB, a plurality of memory packages and a plurality of first anti-impact bars. The PWB is rectangular in shape and has two longer sides and two shorter sides, wherein a plurality of gold fingers are disposed on one of the longer sides and at least an arc notch is formed at each two shorter side respectively. The memory packages are mounted on at least a surface of the PWB. The first anti-impact bars are disposed on the surface of the PWB, adjacent to the two shorter sides and higher than the memory packages in height.

With regard to the memory module mentioned above, the memory packages may be BGA packages including a plurality of solder balls.

With regard to the memory module mentioned above, the PWB may have a plurality of ball-mounting pads for bonding the solder balls.

With regard to the memory module mentioned above, the ball-mounting pads may be NSMD pads (Non-Solder Mask Defined pad).

With regard to the memory module mentioned above, the first anti-impact bars may be made from low-modulus elastic material without function of electrical connection.

With regard to the memory module mentioned above, the first anti-impact bars may be adhesive strips made of glass fiber reinforced resin.

With regard to the memory module mentioned above, some of the first anti-impact bars located at a same shorter side may be arranged in line.

With regard to the memory module mentioned above, at least a second anti-impact bar may be formed at another longer side far away from the gold fingers on the PWB.

With regard to the memory module mentioned above, the memory module is a DIMM (Dual In-Line Memory Module).

With regard to the memory module mentioned above, some of the memory packages may be disposed on the opposing surface of the PWB and some of the first anti-impact bars are also disposed on the opposing surface of the PWB.

With regard to the memory module mentioned above, the mass density of the first anti-impact bars is not greater than that of the PWB.

### DESCRIPTION OF THE DRAWINGS

FIG. 1 is a plan view of a known memory module.

FIG. 2 is a diagram illustrating drop test that the known memory module falls from a height and diverse angles.

FIG. 3 is a partial cross-sectional view illustrating broken place of solder ball of the known memory module after drop test.

FIG. 4 is a plan view of a memory module in accordance with the first embodiment of the present invention.

FIG. 5 is a lateral view of the memory module in accordance with the first embodiment of the present invention.

FIG. 6 is a partial cross-sectional view of the memory module in accordance with the first embodiment of the present invention.

FIG. 7 is a plan view of another memory module in accordance with the second embodiment of the present invention.

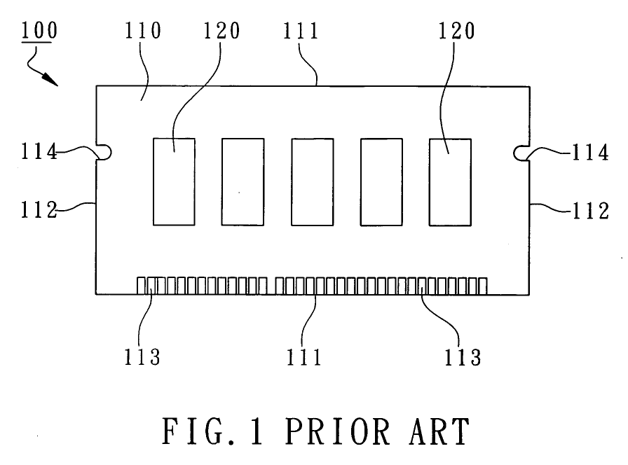

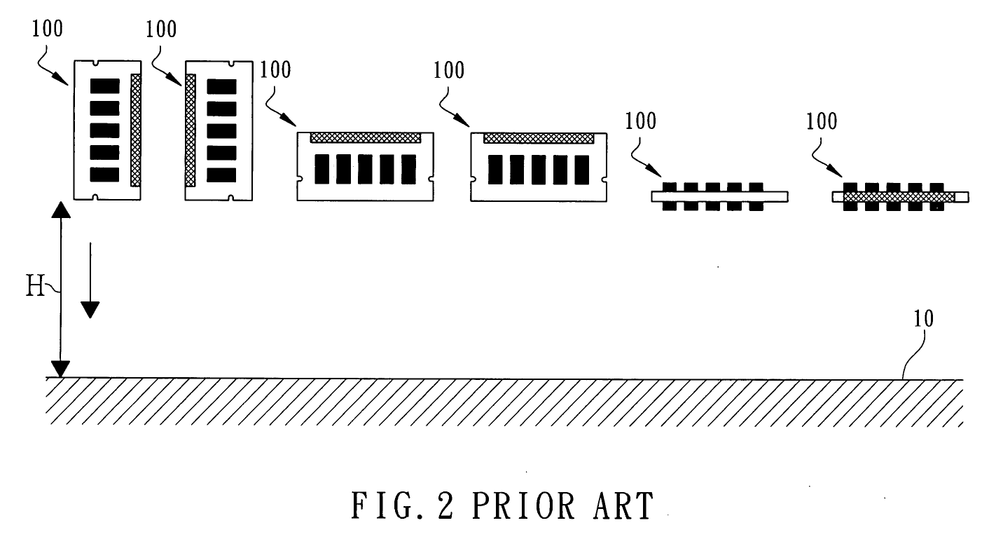

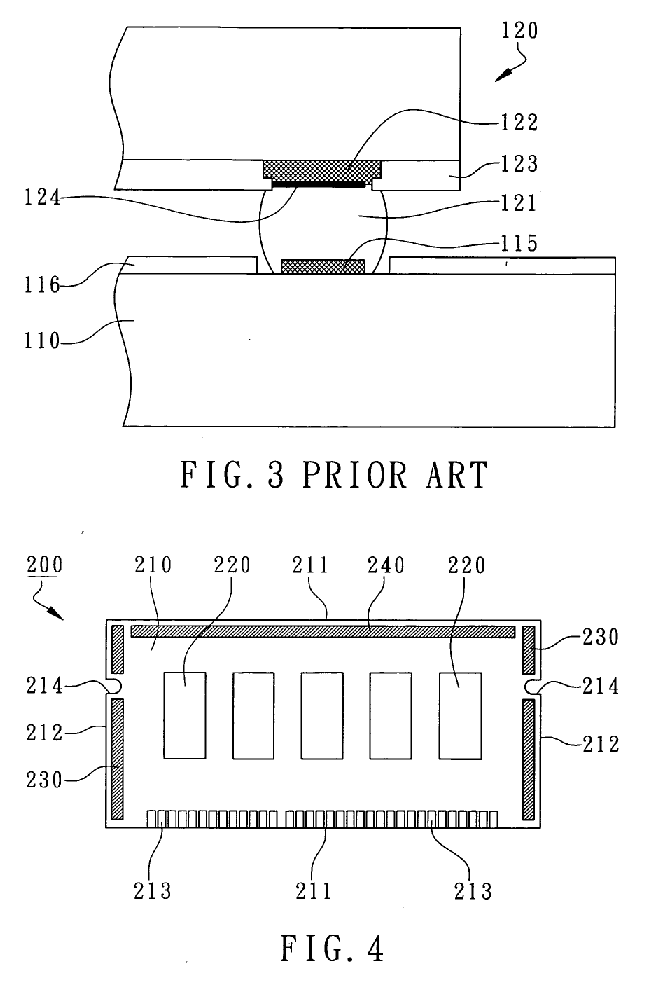

### DETAILED DESCRIPTION OF THE INVENTION

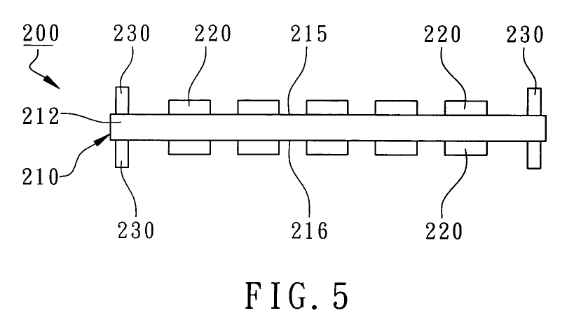

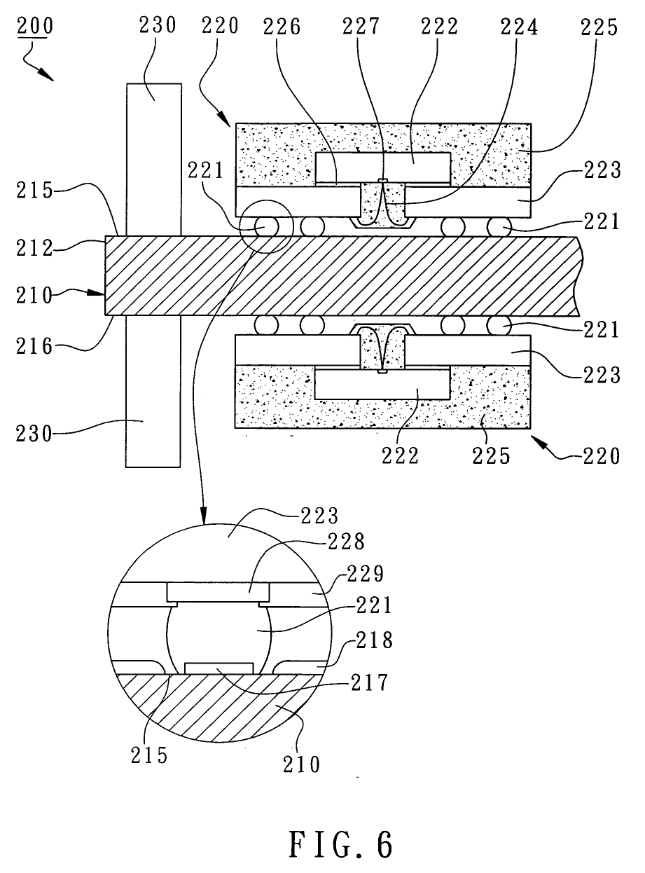

An anti-impact memory module is disclosed according to the first embodiment of the present invention. FIG. 4 is a plan view of the memory module, FIG. 5 is a lateral view of the memory module and FIG. 6 is a partial cross-sectional view of the memory module. The memory module 200 mainly comprises a multi-layer PWB 210, a plurality of memory packages 220 and a plurality of first anti-impact bars 230, and further has appropriate amount of passive component such as capacitors, resistors (not showed in the drawings).

The PWB 210 is rectangular in shape and has two longer sides 211 and two longer shorter sides 212, wherein one of the longer side 211 having a plurality of gold fingers 213 is configured to be plugged into memory socket (not showed in the drawings) of mother board in computer or notebook micro computer. At least an arc notch 214 is formed at each of the two shorter sides 212 respectively. The arc notches 214 can be fastened with two retainers located at two sides of memory slot to permit the memory module 200 to be fixed with the corresponding memory sockets without separation. Moreover, the PWB 210 has an upper surface 215 and a lower surface 216 oppositely. In this embodiment, the memory module 200 may be applied to SO-DIMM (Small Outline Dual In-Line Memory Module) for application of notebook micro computer and there are a plurality of double-sided and electrically independent gold fingers 213 formed along a same longer side 211 on the upper surface 215 and on the lower surface 216 respectively.

The memory packages 220 are disposed on single or dual surface(s) of the PWB 210, such as on the upper surface 215 or the lower surface 216 or both the upper and lower surfaces 215, 216 of the PWB 210. With reference to FIG. 5 and FIG. 6, the memory packages 220 are disposed on the upper surface 215 as well as on the lower surface 216 of the PWB 210 and some of the first anti-impact bars 230 are also disposed on the lower surface 216. In this embodiment with reference to FIG. 6, the memory packages 220 may be arranged in BGA (Ball Grid Array) including a plurality of solder balls 221 and may be in packaging type of fine pitch BGA package or window BGA package. At least a memory chip 222, DRAM memory chip is utilized in general, is sealed inside each memory package 220 to make up memory package products, such as DDR2, DDR3, Rambus. Each of the memory packages 220 may further comprise a substrate 223 for transmission of electrical signal, a plurality of bonding wires 224 for electrical interconnection and an encapsulant 225 of electrical insulation. The chip 222 is adhered on the substrate 223 by a layer of chip-bonding material 226 but the bonding pads 227 of the chip 222 cannot be covered by the substrate 223. The bonding wires 224 pass through a slot of the substrate 223 and electrically connect the bonding pads 227 of the chip 222 with the substrate 223. The chip 222 and the bonding wires 224 are sealed with the encapsulant 225. The solder balls 221 are bonded onto the ball pads 228 located on an exposed surface of the substrate 223, wherein the ball pads 228 are exposed on a solder resist layer 229 on the exposed surface of the substrate 223. The ball pads 228 may typically be SMD pads (Solder Mask Defined pad) or NSMD pads (Non-Solder Mask Defined pad). “SMD pads” means that perimeters of the ball pads 228 are covered by the solder resist layer 229. In case of SMD pads of round shape, the openings of the solder resist layer 229 are smaller than the ball pads 228 in diameter. Comparatively, “NSMD pads” means that perimeters of the ball pads 228 are not covered by the solder resist layer 229. In case of NSMD pads, the openings of the solder resist layer 229 are larger than the ball pads 228 in diameter.

With reference to FIG. 6, a plurality of ball-mounting pads 217 may be disposed on the PWB 210 for mounting the solder balls 221. Preferably, the ball-mounting pads 217 are NSMD pads, which means the outsides of the ball-mounting pads 217 are not covered and defined by the solder resist layer 229 of the PWB 210 so as to improve mounting strength of the ball-mounting pads 217 and the corresponding solder balls 221 and lower the occurring possibility of crack at the mounting interface between the ball-mounting pads 217 and the solder balls 221. However, it is unlimited that the ball-mounting pads 217 may also be SMD pads.

The first anti-impact bars 230 are disposed on the surfaces 215, 216 of the PWB 210 and located adjacent to the two shorter sides 212. Since the first anti-impact bars 230 are higher than the memory packages 220 in height, instead of the memory packages 220 the first anti-impact bars 230 will directly collide with the ground while the memory module 200 is fallen accidentally or during drop test to widely reduce impact stress directly conducted to the memory packages 220. Thus, the problem of that the mounting interfaces between the solder balls 221 and the ball pads 228 are subject to crack will be solved with obvious anti-impact efficiency. In this embodiment, the first anti-impact bars 230 located at a same shorter side 212 may be arranged in line and made from impact-absorbing material without function of electrical connection, such as silica strip, rubber strip, polyimide strip or BT resin strip. The first anti-impact bars 230 may also be adhesive strips made of glass fiber reinforced resin, such as FR-3 and FR-4. Preferably, the mass density of the first anti-impact bars 230 is not greater than that of the PWB 210 to avoid from excessively increasing total weight of the memory module 200 to affect drop test result. In this embodiment, at least a second anti-impact bar 240 is formed at the other longer side 211 far away from the gold fingers 213 on the PWB 210.

Besides, when the memory module 200 is not plugged into a memory socket, it can be flatly placed on a table or any kind of carriers and contacts table with the first anti-impact bars 230 and/or the second anti-impact bars 240, so that the memory packages 220 will be suspended in the air without collision from external force. In addition, user may catch the first anti-impact bars 230 and/or the second anti-impact bars 240 of electrical insulation while taking the memory module 200 without directly contacting the memory packages 220 so as to lower possibility of electrostatic discharge that might destroy memory chips. Within the second embodiment, another anti-impact memory module is disclosed, which may be suitable for desk-top computer, such as standards of DDR400, DDR2-533, DDR2-667 and DDR2-800, etc.

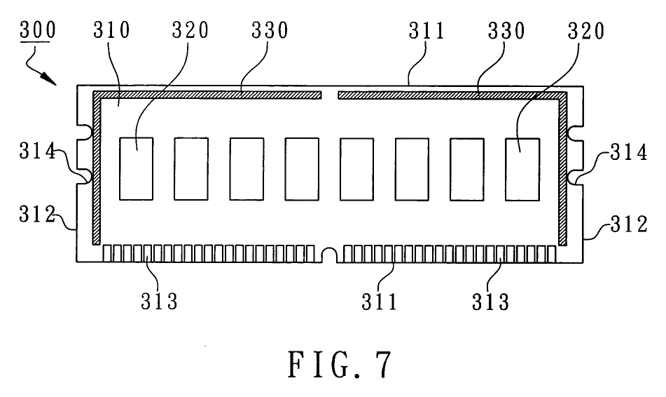

With reference to FIG. 7, the memory module 300 mainly comprises a multi-layer PWB 310, a plurality of memory packages 320 and a plurality of anti-impact bars 330. The PWB 310 is rectangular in shape and has two longer sides 311 and two shorter sides 312. A plurality of gold fingers 313 are disposed along one of the longer sides 311 and at least an arc notch 314 is formed at each of the two shorter sides 312 respectively. The memory packages 320 are disposed on at least a surface of the PWB 310 and may be formed on single or dual surface(s) of the PWB 310.

The anti-impact bars 330 are disposed on the surface of the PWB 310 and adjacent to the two shorter sides 312 and higher than the memory packages 320 in height. In this embodiment, the anti-impact bars 330 may be integrally joined with the memory module 300 in “L” shape to improve impact resistance, thereby preventing the joint interfaces between the PWB 310 and the memory packages 320 from crack with obvious function of anti-impact.

While the present invention has been particularly illustrated and described in detail with respect to the preferred embodiments thereof, it will be clearly understood by those skilled in the art that various changed in form and details may be made without departing from the spirit and scope of the present invention

What is claimed is:

1. A memory module comprising:
a multi-layer PWB (printed wiring board) in rectangular shape having two longer sides and two shorter sides, the PWB having a plurality of gold fingers disposed along one of the longer sides and at least an arc notch disposed at each shorter side respectively;
a plurality of memory packages mounted on at least a surface of the PWB; and
a plurality of first anti-impact bars disposed on the surface of the PWB and adjacent to the two shorter sides, wherein the first anti-impact bars are higher than the memory packages in height.

2. The memory module in accordance with claim 1, wherein the memory packages are BGA packages including a plurality of solder balls.

3. The memory module in accordance with claim 2, wherein the PWB has a plurality of ball-mounting pads on the surface for bonding the solder balls.

4. The memory module in accordance with claim 3, wherein the ball-mounting pads are NSMD pads (Non-Solder Mask Defined pad).

5. The memory module in accordance with claim 1, wherein the first anti-impact bars are made from low-modulus elastic material without function of electrical connection.

6. The memory module in accordance with claim 1, wherein the first anti-impact bars are adhesive strips made of glass fiber reinforced resin.

7. The memory module in accordance with claim 1, wherein some of the first anti-impact bars located at a same shorter side are arranged in line.

8. The memory module in accordance with claim 1, further comprising at least a second anti-impact bar formed at the other longer side far away from the gold fingers on the PWB.

9. The memory module in accordance with claim 1, wherein the memory module is a DIMM (Dual In-Line Memory Module).

10. The memory module in accordance with claim 1, wherein some of the memory packages are mounted on the opposing surface of the PWB and some of the first anti-impact bars are also disposed on the opposing surface of the PWB.

11. The memory module in accordance with claim 1, wherein the mass density of the first anti-impact bars is not greater than that of the PWB.
